(19) United States
(12) Patent Application Publication
(10) Pub. No.: US 2011/0014432 A1
(43) Pub. Date: Jan. 20, 2011

(54) HYDROPHILIC SHEET AND METHOD OF IMPARTING ULTRAHIGH HYDROPHILICITY TO SURFACE OF BASE MATERIAL

(75) Inventor: Yoshio Terada, Ibaraki-shi (JP)

Correspondence Address: SUGHRUE MION, PLLC, 2100 PENNSYLVANIA AVENUE, N.W., SUITE 800, WASHINGTON, DC, 20037, US

(73) Assignee: NITTO DENKO CORPORATION, Ibaraki-shi, Osaka (JP)

(21) Appl. No.: 12/933,329

(22) PCT Filed: Feb. 16, 2009
(86) PCT No.: PCT/JP2009/052483

§ 371 Date: Sep. 17, 2010

(30) Foreign Application Priority Data
Mar. 19, 2008 (JP) 2008-071396
Mar. 19, 2008 (JP) 2008-071397

(51) Int. Cl. B32B 3/00; C23C 16/44; C23C 16/48

(52) U.S. Cl. 428/172; 427/248.1; 427/596

(57) ABSTRACT

Provided is a hydrophilic sheet which has high wettability by water, from which an adherent fouling substance or adherent foreign matter can be easily removed by washing with water, and which can be prevented from fogging due to water-drop adhesion. Also provided is a method of imparting high wettability by water to the surface of any appropriate base material. A hydrophilic sheet of the present invention includes, on a surface of a support, an assembly layer of oblique columnar structures each protruding at an elevation angle from the surface of less than 90°, and the surface of the assembly layer has a water contact angle of 10° or less. In addition, a method of imparting ultrahigh hydrophilicity to a surface of a base material the present invention is a method of imparting ultrahigh hydrophilicity to the surface of the base material, the method including forming, on the surface of the base material, an assembly layer of oblique columnar structures each protruding at an elevation angle from the surface of less than 90° by an oblique deposition process.

### TECHNICAL FIELD

The present invention relates to a hydrophilic sheet having high wettability by water. To be specific, the present invention relates to a hydrophilic sheet such as: an anti-fouling sheet from which an adherent fouling substance or adherent foreign matter can be easily removed by washing with water; or an anti-fogging sheet that can be prevented from fogging due to water-drop adhesion.

In addition, the present invention relates to a method of imparting ultrahigh hydrophilicity to a surface of a base material, and more specifically, to a method of imparting high wettability by water to the surface of any appropriate base material. According to the method of the present invention, a fouling substance or foreign matter adhering to a surface of a base material can be easily removed by washing with water, and the fogging of the surface of the base material due to water-drop adhesion can be prevented.

The hydrophilic sheet of the present invention can be preferably obtained by employing the method of imparting ultrahigh hydrophilicity to a surface of a base material of the present invention.

### BACKGROUND ART

The adhesion of fouling substances to members used outdoors due to, for example, air pollution, the flying of yellow sand, or the dispersal of pollen has been recognized as a serious problem in recent years.

On the other hand, a solar cell technology has become widespread as an alternative to fossil energy. In addition, buildings each using a large number of glass windows for sufficiently taking in sunlight have started to attract popularity, and hence the frequency at which glass panels are utilized outdoors has been abruptly increasing these days. Any such glass panel is requested to surely take in sunlight. In addition, a fouling substance on its external appearance is apt to be conspicuous, and hence a periodic cleaning operation is needed. However, it is difficult to perform the cleaning operation frequently because any such glass panel is often placed in a high, narrow place. In view of the foregoing, a member used outdoors from which a fouling substance can be easily removed has been requested (see, for example, Patent Document 1).

Meanwhile, users' demands for the prevention of the adhesion of fouling substances to members used indoors have become more and more stringent year by year.

The frequency at which a large indefinite number of persons (skins) directly contact members used in water sections typified by a bath, a kitchen, and a water closet out of the members used indoors is particularly high. Accordingly, the adhesion of a fouling substance such as a water deposit, saprolegnia, or a soap residue has been recognized as a problem from the viewpoints of an external appearance and hygiene.

In addition, fogging has conventionally occurred owing to water-drop adhesion in, for example, traffic signs, display panels, and mirrors used in water sections, and the fogging leads to a problem such as a reduction in visibility.

### Patent Document 1: JP 2002-52667 A

### DISCLOSURE OF THE INVENTION

### Problems to be Solved by the Invention

An object of the present invention is to provide a hydrophilic sheet which has high wettability by water, from which an adherent fouling substance or adherent foreign matter can be easily removed by washing with water, and which can be prevented from fogging due to water-drop adhesion.

Another object of the present invention is to provide a method of imparting ultrahigh hydrophilicity to a surface of a base material suitable for obtaining the above-mentioned hydrophilic sheet, that is, a method of imparting high wettability by water to the surface of any appropriate base material.

### Means for Solving the Problems

A hydrophilic sheet of the present invention includes, on a surface of a support, an assembly layer of oblique columnar structures each protruding at an elevation angle from the surface of less than 90°, and the surface of the assembly layer has a water contact angle of 10° or less.

In a preferred embodiment, the hydrophilic sheet includes, on one surface of the above-mentioned support, the assembly layer of the oblique columnar structures each protruding at an elevation angle from the surface of less than 90°, the surface of the assembly layer has a water contact angle of 10° or less, and a pressure-sensitive adhesive layer is formed on the other surface of the above-mentioned support.

In a preferred embodiment, the above-mentioned assembly layer includes an anti-fouling layer.

In a preferred embodiment, the above-mentioned assembly layer includes an anti-fogging layer.

A method of imparting ultrahigh hydrophilicity to a surface of abase material of the present invention is a method of imparting ultrahigh hydrophilicity to the surface of the base material, the method including forming, on the surface of the base material, an assembly layer of oblique columnar structures each protruding at an elevation angle from the surface of less than 90° by an oblique deposition process.

In a preferred embodiment, a vacuum deposition apparatus is used in the above-mentioned oblique deposition process.

In a preferred embodiment, an ultimate pressure in the above-mentioned vacuum deposition apparatus is 1×10⁻³ torr or less.

In a preferred embodiment, vapor deposition of a deposition material in the above-mentioned vacuum deposition apparatus is performed by heating and vaporization with electron beams.

In a preferred embodiment, the above-mentioned oblique deposition process is performed by depositing a deposition material from the vapor onto the above-mentioned base material delivered by a roll.

In a preferred embodiment, the above-mentioned oblique deposition process involves obliquely depositing a deposition material from the vapor onto the above-mentioned base material by providing a partial shield between a deposition source and the base material.

In a preferred embodiment, the above-mentioned assembly layer has a thickness of 10 nm or more.

In a preferred embodiment, the number of the above-mentioned oblique columnar structures per unit area of the surface of the above-mentioned base material is 1×10⁸ structures/cm² or more.

In a preferred embodiment, the surface of the above-mentioned assembly layer has a water contact angle of 10° or less.

### Effects of the Invention

According to the present invention, there can be provided a hydrophilic sheet which has high wettability by water, from which an adherent fouling substance or adherent foreign matter can be easily removed by washing with water, and which can be prevented from fogging due to water-drop adhesion.

Any such effect as described above can be expressed by: providing a surface of a support with an assembly layer of oblique columnar structures each protruding at an elevation angle from the surface of less than 90°; setting the water contact angle of the surface of the assembly layer to 10° or less; and causing the assembly layer of the oblique columnar structures to function as a highly hydrophilic layer.

In addition, according to the present invention, high wettability by water can be imparted to the surface of any appropriate base material. According to the present invention, a fouling substance or foreign matter adhering to the surface of the base material can be easily removed by washing with water, and the fogging of the surface of the base material due to water-drop adhesion can be prevented.

Any such effect as described above can be expressed by forming, on the surface of the base material, an assembly layer of oblique columnar structures each protruding at an elevation angle from the surface of less than 90° by an oblique deposition process.

In other words, providing the surface of a support or base material with an assembly layer of oblique columnar structures each protruding at an elevation angle from the surface of less than 90° can impart high wettability to the surface of the assembly layer on the basis of a fractal theory.

Here, the fractal theory is a theory for imparting ultrahigh hydrophilicity to a surface in which a hydrophilic effect is additionally strengthened by fine irregularities on the surface. When fine irregular structures (fractal structures) are formed on the surface, the surface adsorbs moisture in the air so that a fine water film may be formed in a recessed portion. As a result, the hydrophilicity of the entire surface is improved. Therefore, even when foreign matter or a fouling substance adheres to such surface, the foreign matter or the fouling substance does not completely fix on the surface, but maintains a floating state. Then, the application of water (washing with water) in the state results in the permeation of water into an interface between the surface and the foreign matter or the fouling substance, and hence the foreign matter or the fouling substance can be easily removed. In the natural world, the anti-fouling based on the fractal theory is known as the anti-fouling function of the shell of a snail.

In addition, a water contact angle of 10° or less is generally referred to as “ultrahigh hydrophilicity,” and a water drop is of such a form as to stick flatly, and does not form any water film but falls down. Therefore, in such case, no water drops adhere, and an anti-fogging effect can be expressed.

### BRIEF DESCRIPTION OF THE DRAWINGS

FIG. 1 is a schematic sectional view of a preferred embodiment of a hydrophilic sheet of the present invention or a hydrophilic member obtained by a method of the present invention.

FIG. 2 is a schematic sectional view of a preferred embodiment of the hydrophilic sheet of the present invention or the hydrophilic member obtained by the method of the present invention.

FIG. 3 is a schematic sectional view of a preferred embodiment of the hydrophilic sheet of the present invention or the hydrophilic member obtained by the method of the present invention, the schematic sectional view describing an elevation angle α.

FIG. 4 is a schematic sectional view of a preferred embodiment of an oblique columnar structure in the hydrophilic sheet of the present invention or the hydrophilic member obtained by the method of the present invention.

FIG. 5 is a schematic sectional view of a preferred embodiment of the oblique columnar structure in the hydrophilic sheet of the present invention or the hydrophilic member obtained by the method of the present invention.

FIG. 6 is a schematic sectional view of a preferred embodiment of an apparatus used in an oblique deposition process.

FIG. 7 is an SEM photograph of a section of a hydrophilic sheet obtained in Example 1.

FIG. 8 is an SEM photograph of a section of a hydrophilic sheet obtained in Example 2.

FIG. 9 is a photograph view of evaluation for anti-fogging performance.

### DESCRIPTION OF SYMBOLS

10 support or base material

20 assembly layer

30 oblique columnar structures

40 pressure-sensitive adhesive layer

50 shield

60 deposition source

70 deposition roll

100 hydrophilic sheet or member

200 hydrophilic sheet or member

### BEST MODE FOR CARRYING OUT THE INVENTION

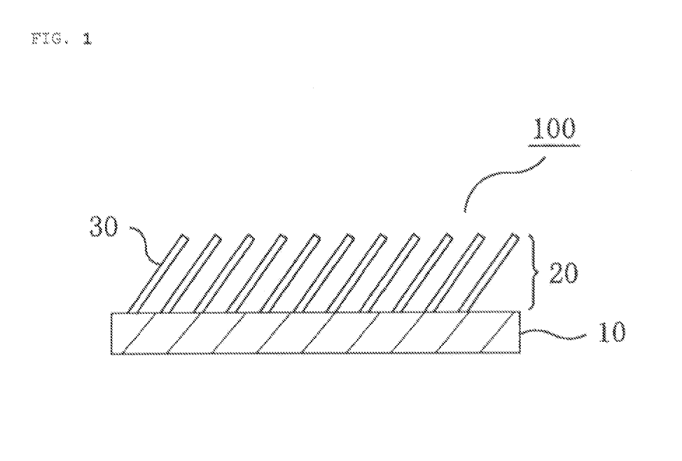

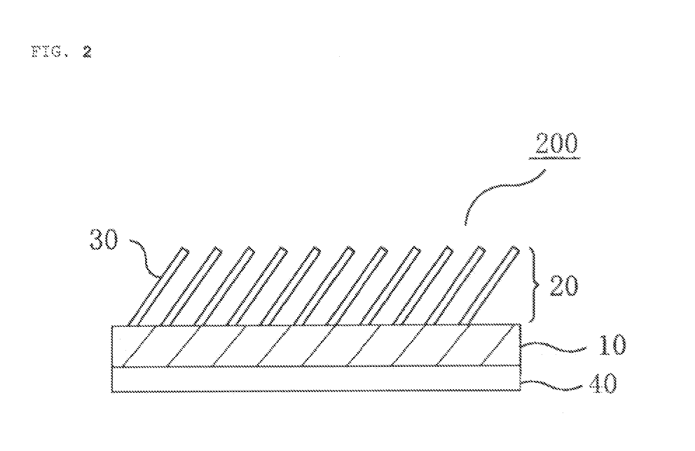

FIGS. 1 and 2 are each a schematic sectional view of a hydrophilic sheet as a preferred embodiment of the present invention or a hydrophilic member as a preferred embodiment obtained by a method of the present invention.

When FIG. 1 is a schematic sectional view of the hydrophilic sheet, a hydrophilic sheet 100 illustrated in FIG. 1 has a support 10 and an assembly layer 20 of oblique columnar structures 30. The assembly layer 20 of the oblique columnar structures 30 maybe provided on one surface of the support 10, or may be provided on each of both surfaces of the support. In addition, the assembly layer 20 of the oblique columnar structures 30 maybe provided on the entirety of the surface of the support 10 provided with the layer, or may be provided only on part of the surface of the support 10.

When FIG. 1 is a schematic sectional view of the hydrophilic member, a hydrophilic member 100 illustrated in FIG. 1 has a base material 10 and the assembly layer 20 of the oblique columnar structures 30. The assembly layer 20 of the oblique columnar structures 30 may be provided on one surface of the base material 10, or maybe provided on each of both surfaces of the base material. In addition, the assembly layer 20 of the oblique columnar structures 30 maybe provided on the entirety of the surface of the base material 10 provided with the layer, or may be provided only on part of the surface of the base material 10.

When FIG. 2 is a schematic sectional view of the hydrophilic sheet, a hydrophilic sheet 200 illustrated in FIG. 2 has the assembly layer 20 of the oblique columnar structures 30 on one surface of the support 10 and a pressure-sensitive adhesive layer 40 on the other surface of the support 10. The pressure-sensitive adhesive layer 40 may be provided on the entirety of the one surface of the support 10, or may be provided only on part of the one surface of the support 10. The assembly layer 20 of the oblique columnar structures 30 may be provided on the entirety of the surface of the support 10 provided with the layer, or may be provided only on part of the surface of the support 10.

When FIG. 2 is a schematic sectional view of the hydrophilic member, a hydrophilic member 200 illustrated in FIG. 2 has the assembly layer 20 of the oblique columnar structures 30 on one surface of the base material 10 and the pressure-sensitive adhesive layer 40 on the other surface of the base material 10. The pressure-sensitive adhesive layer 40 maybe provided on the entirety of the one surface of the base material 10, or may be provided only on part of the one surface of the base material 10. The assembly layer 20 of the oblique columnar structures 30 may be provided on the entirety of the surface of the base material 10 provided with the layer, or may be provided only on part of the surface of the base material 10.

As illustrated in each of FIGS. 1 and 2, the assembly layer 20 of the oblique columnar structures in the present invention is an assembly layer of the multiple oblique columnar structures 30. The assembly layer 20 of the oblique columnar structures can act as an anti-fouling layer or an anti-fogging layer.

The hydrophilic sheet of the present invention or the hydrophilic member obtained by the method of the present invention includes the assembly layer of the oblique columnar structures, and hence numberless fine irregular structures can be formed on its surface. As a result, the hydrophilic sheet or the hydrophilic member expresses high wettability by water and is effective particularly in preventing fouling or fogging.

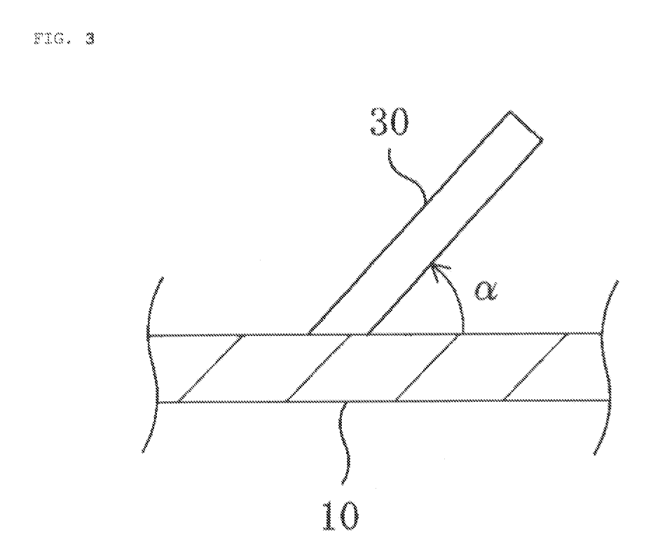

As illustrated in FIG. 3, the oblique columnar structures 30 each protrude from the surface of the support or base material 10 at an elevation angle α from the surface of less than 90°. The elevation angle α is preferably 10 to 85°, more preferably 20 to 80°, or still more preferably 30 to 70°. When the elevation angle α is less than 90°, the hydrophilic sheet of the present invention or the hydrophilic member obtained by the method of the present invention is as described below. That is, the sheet or the member has high wettability by water, an adherent fouling substance or adherent foreign matter can be easily removed from the sheet or the member by washing with water, and the sheet or the member can be prevented from fogging due to water-drop adhesion.

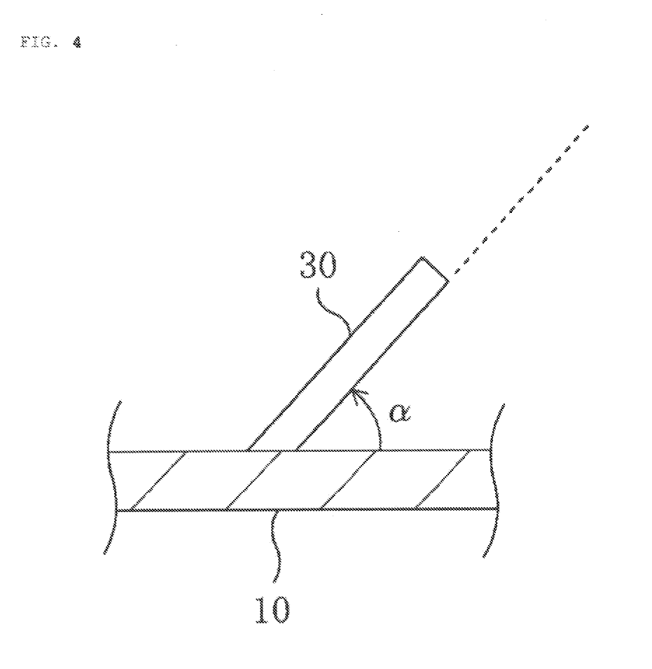

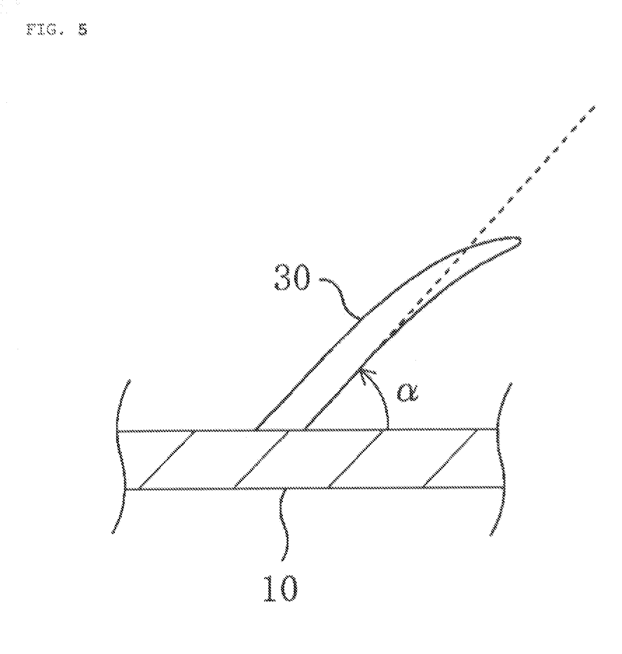

As illustrated in FIG. 4, the oblique columnar structures 30 may each protrude from the surface of the support or base material 10 at the elevation angle α in a substantially straight fashion. Alternatively, as illustrated in FIG. 5, the oblique columnar structures 30 may each be of a sinuous shape after having protruded from the surface of the support or base material 10 at the initial elevation angle α.

The oblique columnar structures each have a columnar structure. The term “columnar structure” comprehends not only a strictly columnar structure but also a substantially columnar structure. Preferred examples of the columnar structure include a cylindrical structure, a polygonal columnar structure, a cone-like structure, and a fibrous structure. In addition, the sectional shape of the columnar structure maybe uniform over the entirety of the columnar structure, or may be nonuniform.

In the hydrophilic sheet of the present invention or the hydrophilic member obtained by the method of the present invention, the surface of the assembly layer of the oblique columnar structures has a water contact angle of 10° or less, preferably 8° or less, or more preferably 6° or less. When the water contact angle of the surface of the assembly layer of the oblique columnar structures is set to fall within the above-mentioned range, the sheet or the member has high wettability by water, an adherent fouling substance or adherent foreign matter can be easily removed from the sheet or the member by washing with water, and the sheet or the member can be prevented from fogging due to water-drop adhesion.

The oblique columnar structures in the hydrophilic sheet of the present invention or the hydrophilic member obtained by the method of the present invention each have an aspect ratio of preferably 1 or more, more preferably 2 to 20, or still more preferably 3 to 10. The term “aspect ratio” as used in the present invention refers to a ratio between the length (A) of each of the oblique columnar structures and the length (B) of the diameter of a portion having the thickest diameter of the oblique columnar structure (provided that the lengths (A) and (B) have the same unit). When the aspect ratio of each of the oblique columnar structures falls within the above-mentioned range, the sheet or the member has high wettability by water, an adherent fouling substance or adherent foreign matter can be easily removed from the sheet or the member by washing with water, and the sheet or the member can be prevented from fogging due to water-drop adhesion.

The oblique columnar structures in the hydrophilic sheet of the present invention or the hydrophilic member obtained by the method of the present invention each have a length of preferably 100 nm or more, more preferably 200 to 100,000 nm, still more preferably 300 to 10,000nm, or particularly preferably 500 to 5000 nm. When the length of each of the oblique columnar structures falls within the above-mentioned range, the sheet or the member has high wettability by water, an adherent fouling substance or adherent foreign matter can be easily removed from the sheet or the member by washing with water, and the sheet or the member can be prevented from fogging due to water-drop adhesion.

The oblique columnar structures in the hydrophilic sheet of the present invention or the hydrophilic member obtained by the method of the present invention each have a diameter of preferably 1000 nm or less, more preferably 10 to 500 nm, or still more preferably 100 to 300 nm. When the diameter of each of the oblique columnar structures falls within the above-mentioned range, the sheet or the member has high wettability by water, an adherent fouling substance or adherent foreign matter can be easily removed from the sheet or the member by washing with water, and the sheet or the member can be prevented from fogging due to water-drop adhesion.

The length and diameter of the oblique columnar structures in the hydrophilic sheet of the present invention or the hydrophilic member obtained by the method of the present invention have only to be measured by any appropriate measurement method. The measurement is preferably performed with, for example, a scanning electron microscope (SEM) in terms of ease of measurement and the like. In the case of the measurement with the scanning electron microscope (SEM), the length and diameter of the oblique columnar structures can be determined by, for example, sticking the hydrophilic sheet of the present invention to an SEM observation sample board and observing the hydrophilic sheet from a side direction.

The number of the oblique columnar structures per unit area of the surface of the support or base material in the hydrophilic sheet of the present invention or the hydrophilic member obtained by the method of the present invention is preferably 1×10⁸ structures/cm²or more, more preferably 1×10⁸ to 1×10¹² structures/cm², or still more preferably 3×10⁸ to 1×10¹⁰ structures/cm². When the number of the oblique columnar structures per unit area of the surface of the support or base material falls within the above-mentioned range, the sheet or the member has high wettability by water, an adherent fouling substance or adherent foreign matter can be easily removed from the sheet or the member by washing with water, and the sheet or the member can be prevented from fogging due to water-drop adhesion.

Any appropriate material can be adopted for the support in the hydrophilic sheet of the present invention. For example, there are used: a sheet or a substrate formed of an organic polymer resin such as a polyimide (PI) -based resin, a polyester (PET)-based resin, a polyethylene naphthalate (PEN)-based resin, a polyether sulfone (PES)-based resin, a polyether ether ketone (PEEK)-based resin, a polyarylate (PAR)-based resin, an aramid-based resin, a liquid crystal polymer (LCP) resin, a fluorine-based resin, an acrylic resin, an epoxy-based resin, a polyolefin-based resin, polyvinyl chloride, EVA, PMMA, or POM; and also a substrate formed of, for example, an inorganic material such as a quartz substrate, a glass substrate, or a silicon wafer. Of those, a PET-based resin sheet and a polycarbonate-based resin sheet are particularly suitably used because their transparency is high.

Any appropriate material can be adopted for the base material in the hydrophilic member obtained by the method of the present invention. For example, there are used: an organic polymer resin such as a polyimide (PI)-based resin, a polyester (PET)-based resin, a polyethylene naphthalate (PEN)-based resin, a polyether sulfone (PES)-based resin, a polyether ether ketone (PEEK)-based resin, a polyarylate (PAR)-based resin, an aramid-based resin, a liquid crystal polymer (LCP) resin, a fluorine-based resin, an acrylic resin, an epoxy-based resin, a polyolefin-based resin, polyvinyl chloride, EVA, PMMA, or POM; and inorganic materials such as quartz, glass, a silicon wafer, concrete, mortar, a siding board, a tile, a ceramic, a mirror, a metal (such as iron, aluminum, alloy metal, steel, or copper), stone, wood, slate, and the like.

To be more specific, examples of the support in the hydrophilic sheet of the present invention or the base material in the hydrophilic member obtained by the method of the present invention classified into applications include:
(1) traffic-related materials such as a tunnel interior plate, lighting in a tunnel, a traffic sign, traffic lighting, a soundproof wall, a guard fence, a reflecting plate, and a traffic mirror;
(2) housing-related materials such as a kitchen equipment member, a bathroom equipment member, a housing interior member, a siding material, a tile, a glass, a sash, a braided door, a gate, a car port, a sunroom, a veranda member, a roofing member, a housing exterior wall member, a bathroom mirror, a makeup mirror, and sanitary ware;
(3) building-related materials such as a building sash, a curtain wall, a coated steel plate, an aluminum panel, a tile, a stone, a crystallized glass, and a film for glass;
(4) shop-related materials such as a showcase, signs and displays, a show window, a covering material for a shop, a case for refrigerated goods, and a case for frozen goods;
(5) agriculture-related materials such as a glass greenhouse and a vinyl house;
(6) electronics-related materials such as a computer display, a solar cell, a glass, an aluminum fan for an air conditioner, and a high-voltage cable;
(7) vehicle-related materials such as an automobile body, a vehicle body, an automobile coated member, a vehicle coated member, a headlight cover, a window glass, a helmet shield, a film for glass, a door mirror, a two-wheeler rear-view mirror, a two-wheeler windshield, and a film for a mirror;
(8) optical instrument-related materials such as an optical lens and an endoscope lens;
(9) medical materials such as a contact lens and a catheter; and
(10) commodity/consumption goods-related materials such as an eating utensil, a cooking utensil, an anti-fouling maintenance material, and an anti-fogging maintenance material.

In the hydrophilic sheet of the present invention or the hydrophilic member obtained by the method of the present invention, adhesiveness between each of the oblique columnar structures and the support may be improved by subjecting the surface of the support or base material to a plasma (sputtering) treatment, corona discharge, ultraviolet irradiation, a flame, electron beam irradiation, chemical conversion, an etching treatment such as oxidation, or an undercoating treatment with organic matter in advance. Alternatively, the surface may be subjected to dusting and cleaning by solvent cleaning, ultrasonic cleaning, or the like as required.

Any appropriate thickness can be adopted as the thickness of the support or base material in the hydrophilic sheet of the present invention or the hydrophilic member obtained by the method of the present invention. In the case of, for example, a sheet-like support or base material, the thickness is preferably 10 to 250 μm. In the case of a substrate-like support or base material, the thickness is preferably 0.1 to 10 mm. It should be noted that the support or base material may be a single layer, or may be a laminate of two or more layers.

Any appropriate material can be adopted for each of the oblique columnar structures in the hydrophilic sheet of the present invention or the hydrophilic member obtained by the method of the present invention. For example, there may be used: metals such as aluminum, zinc, gold, silver, platinum, nickel, chromium, copper, and indium; inorganic materials such as sapphire, silicon carbide (SiC), and gallium nitride (GaN); and oxides such as silicon monoxide (SiO), silicon dioxide (SiO₂), aluminum oxide (Al₂O₃), cerium oxide (CeO₂), chromium oxide (Cr₂O₃), gallium oxide (Ga₂O₃), hafnium oxide (HfO₂), tantalum pentoxide (Ta₂O₅), yttrium oxide (Y₂O₃), tungsten oxide (WO₃), titanium monoxide (TiO), titanium dioxide (TiO₂), titanium pentoxide (Ti₃O₅), nickel oxide (NiO), magnesium oxide (MgO), ITO (In₂O₃+SnO₂), niobium pentoxide (Nb₂O₅), zinc oxide (ZnO), and zirconium oxide (ZrO₂). Further, there may be used: polyimides; fluorine-based materials such as aluminum fluoride, calcium fluoride, cerium fluoride, lanthanum fluoride, lithium fluoride, magnesium fluoride, neodymium fluoride, and sodium fluoride; resins such as silicone; and the like. Those materials may be used alone or in a mixture, or there may be adopted a multilayer structure of two or more layers. In particular, there are suitably used oxides such as silicon dioxide (SiO₂) and titanium dioxide (TiO₂), which are hydrophilic materials.

The surface of the assembly layer of the oblique columnar structures in the hydrophilic sheet of the present invention or the hydrophilic member obtained by the method of the present invention has a surface free energy of preferably 70 mJ/m² or more, more preferably 73 mJ/m² or more, or still more preferably 75 mJ/m² or more. When the surface free energy of the surface of the assembly layer of the oblique columnar structures falls within the above-mentioned range, the wettability of the surface of the assembly layer is improved, an adherent fouling substance or adherent foreign matter can be easily removed from the sheet or the member by washing with water, and the sheet or the member can be prevented from fogging due to water-drop adhesion.

The term “surface free energy” as used herein refers to a value for the surface free energy of a solid determined by measuring a contact angle with each of water and methylene iodide with respect to the surface of the solid, substituting the measured value and a value for the surface free energy of the liquid for contact angle measurement (known from a document) into the following equation (1) derived from Young's equation and the extended Fawkes's equation, and solving the resultant two equations as simultaneous linear equations.

(1+cos θ)r_{L}=2√(r_{S}^{d}r_{L}^{d})+2√(r_{S}^{v}r_{L}^{v}) (1)

It should be noted that the definition of each of the symbols in the equation is as described below.
θ: The contact angle
r_{L}: The surface free energy of the liquid for contact angle measurement
r_{L}^{d}: A dispersion force component in rL
r_{L}^{v}: A polarity force component in rL
r_{S}^{d}: A dispersion force component in the surface free energy of the solid
r_{S}^{v}: A polarity force component in the surface free energy of the solid

Any appropriate condition can be adopted for the thickness of the assembly layer of the oblique columnar structures in the hydrophilic sheet of the present invention or the hydrophilic member obtained by the method of the present invention to such an extent that the object of the present invention can be achieved. The thickness is preferably 10 nm or more, more preferably 50 to 10,000 nm, or still more preferably 100 to 5000 nm. When the thickness of the assembly layer of the oblique columnar structures falls within such range, the wettability of the surface of the assembly layer is improved, an adherent fouling substance or adherent foreign matter can be easily removed from the sheet or the member by washing with water, and the sheet or the member can be prevented from fogging due to water-drop adhesion.

It is preferred that the assembly layer of the oblique columnar structures in the hydrophilic sheet of the present invention or the hydrophilic member obtained by the method of the present invention be substantially free of any pressure-sensitive adhesiveness. The expression “substantially free of any pressure-sensitive adhesiveness” as used herein refers to a state where a pressure-sensitive tack that epitomizes a function of pressure-sensitive adhesiveness is absent when the essence of pressure-sensitive adhesion is defined as friction as resistance against a slip. The pressure-sensitive tack is such that a pressure-sensitive adhesive expresses a modulus of elasticity of up to 1 MPa in accordance with, for example, Dahlquist's criteria.

A protective film may be used for protecting the surface of the assembly layer of the oblique columnar structures in the hydrophilic sheet of the present invention or the hydrophilic member obtained by the method of the present invention. The protective film can be peeled at an appropriate stage such as the time point at which the sheet or the member is used. A protective film formed of any appropriate material can be used as the protective film. Examples of the protective film include plastic films formed of polyvinyl chloride, a vinyl chloride copolymer, polyethylene terephthalate, polybutylene terephthalate, polyurethane, an ethylene-vinyl acetate copolymer, an ionomer resin, an ethylene-(meth)acrylic acid copolymer, an ethylene-(meth)acrylate copolymer, polystyrene, polycarbonate, or the like, each of which is subjected to peeling treatment with a silicone-based, long-chain alkyl-based, fluorine-based, aliphatic amide-based, or silica-based peeling agent. In addition, the polyolefin resin-based film formed of polyethylene, polypropylene, polybutene, polybutadiene, polymethyl pentene, or the like, has releasing property even without using a releasing treatment agent, and hence, the film alone can be used as a protective film.

The thickness of the protective film is preferably 1 to 100 μm or more preferably 10 to 100 μm. Any appropriate method can be adopted as a method of forming the protective film to such an extent that the object of the present invention can be achieved. The protective film can be formed by, for example, an injection molding method, an extrusion molding method, or a blow molding method.

In a preferred embodiment of the hydrophilic sheet of the present invention, the hydrophilic sheet includes, on one surface of the above-mentioned support, the assembly layer of the oblique columnar structures each protruding at an elevation angle from the surface of less than 90°, the surface of the assembly layer has a water contact angle of 10° or less, and a pressure-sensitive adhesive layer is formed on the other surface of the above-mentioned support.

Any appropriate material can be adopted as a pressure-sensitive adhesive used in the pressure-sensitive adhesive layer in the hydrophilic sheet of the present invention. Examples of the material include acrylic pressure-sensitive adhesives, rubber-based pressure-sensitive adhesives, and silicone-based pressure-sensitive adhesives. Of those, the acrylic pressure-sensitive adhesives are preferred because of, for example, a low extent to which the acrylic pressure-sensitive adhesives each contaminate an adherend, and an acrylic pressure-sensitive adhesive mainly formed of a (meth)acrylic polymer 10 wt % or less of which is accounted for by a component having a weight-average molecular weight of 100,000 or less is particularly preferred.

Examples of a monomer component of the (meth)acrylic polymer preferably include alkyl(meth)acrylates each having an alkyl group of 30 or less carbons such as a methyl group, an ethyl group, an n-propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, or a dodecyl group, or more preferably, alkyl(meth)acrylates each having a linear or branched alkyl group with 4 to 18 carbons. Those alkyl(meth)acrylates may be used alone or in combination.

Examples of a monomer component other than the above-mentioned monomers include a carboxyl group-containing monomer such as acrylic acid, methacrylic acid, carboxyethyl(meth)acrylate, carboxypentyl(meth)acrylate, itaconic acid, maleic acid, fumaric acid, or crotonic acid; an acid anhydride monomer such as maleic anhydride or itaconic anhydride; a hydroxyl group-containing monomer such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxyrauryl(meth)acrylate, or (4-hydroxymethylcyclohexyl)methyl(meth)acrylate; a sulfonate group-containing monomer such as styrenesulfonate, allylsulfonate, 2-(meth)acrylamide-2-methyl propanesulfonate, (meth)acrylamide propanesulfonate, sulfopropyl(meth)acrylate, or (meth)acryloyl oxynaphthalenesulfonate; and a phosphate group-containing monomer such as 2-hydroxyethyl acryloylphosphate. Those monomers may be used alone or in combination.

Further, a polyfunctional monomer may be used for the copolymer monomer component, as required, for the purpose of cross-linking treatment of (meth)acrylic polymer or the like.

Examples of the polyfunctional monomer include hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxy penta(meth)acrylate, dipentaerythritol hexa(meth)acrylate, epoxy(meth)acrylate, polyester(meth)acrylate, urethane(meth)acrylate, and the like. Those polyfunctional monomer components may be used alone or in combination.

The polyfunctional monomer is used at a content of preferably 30 wt % or less, or more preferably 15 wt % or less with respect to all monomer components from the viewpoint of, for example, pressure-sensitive adhesive property.

The (meth)acrylic polymer can be prepared, for example, with a mixture containing one or two or more kinds of monomer components by applying any suitable method such as a solution polymerization method, an emulsion polymerization method, a bulk polymerization method, or a suspension polymerization method.

A polymerization initiator may be used in the preparation of the (meth)acrylic polymer. Examples of the polymerization initiator include peroxides such as hydrogen peroxide, benzoyl peroxide, t-butyl peroxide, and the like.

The polymerization initiator is desirably used alone, but may be combined with a reducing agent and used as a redox type polymerization initiator.

Examples of the reducing agent include ionic salts such as salts of sulfite, bisulfite, iron, copper, or cobalt; amines such as triethanol amine; reducing sugars such as aldose and ketose; and the like.

An azo compound is also preferred as the polymerization initiator and, for example, 2,2′-azobis-2-methylpropioamidine salt, 2,2′-azobis-2,4-dimethylvaleronitrile, 2,2′-azobis-N,N′-dimethyleneisobutylamidine salt, 2,2′-azobisisobutyronitrile, or 2,2′-azobis-2-methyl-N-(2-hydroxyethyl)propionamide can be used.

Polymerization initiators may be used alone or in combination.

The polymerization reaction temperature is preferably 50 to 85° C., and the polymerization reaction time is preferably 1 to 8 hours.

The polymerization method is particularly preferably the solution polymerization method, and a solvent for the (meth)acrylic polymer is preferably a polar solvent such as ethyl acetate or toluene. A solution concentration is preferably 20 to 80 wt %.

A cross-linking agent can be suitably added to the pressure-sensitive adhesive used in the pressure-sensitive adhesive layer in the hydrophilic sheet of the present invention for increasing the number-average molecular weight of the (meth)acrylic polymer as a base polymer.

Examples of the cross-linking agent include polyisocyanate compounds, epoxy compounds, aziridine compounds, melamine resins, urea resins, anhydrous compounds, polyamines, carboxyl group-containing polymers, and the like.

When a cross-linking agent is used, its used amount is preferably 0.01 to 5 weight parts with respect to 100 weight parts of the base polymer so that the peeling pressure-sensitive adhesion will not decrease too much.

Any appropriate additive such as a tackifier, an antioxidant, a filler, or a colorant can be incorporated into the pressure-sensitive adhesive used in the pressure-sensitive adhesive layer in the hydrophilic sheet of the present invention as required.

The pressure-sensitive adhesive layer in the hydrophilic sheet of the present invention has a thickness of preferably 1 to 100 μm, more preferably 3 to 50 μm, or particularly preferably 5 to 20 μm.

A separator is preferably provided on the pressure-sensitive adhesive layer in the hydrophilic sheet of the present invention. When the separator is provided, the laminated sheet (pressure-sensitive sheet) can be subjected to a heat treatment or stored while being brought into a roll shape. In addition, the surface of the pressure-sensitive adhesive layer can be protected from dust or the like until the hydrophilic sheet is used.

The separator is constituted of a material such as a film formed of a plastic such as polyether ether ketone, polyetherimide, polyallylate, polyethylene naphthalate, polyethylene, polypropylene, polybutene, polybutadiene, polymethyl pentene, polyvinyl chloride, a vinyl chloride copolymer, polyethylene terephthalate, polybutylene terephthalate, polyurethane, an ethylene-vinyl acetate copolymer, an ionomer resin, an ethylene-(meth)acrylic acid copolymer, an ethylene-(meth)acrylate copolymer, polystyrene, or polycarbonate.

One surface of the separator may be subjected to a peeling treatment such as a silicone treatment, a long-chain alkyl treatment, a fluorine treatment, a treatment with an aliphatic amide-based agent, or a treatment with a silica-based agent as required in order that its peeling performance from the pressure-sensitive adhesive layer may be improved.

The separator has a thickness of preferably 5 to 200 μm, more preferably 25 to 100 μm, or still more preferably 38 to 60 μm.

The hydrophilic sheet of the present invention can be produced by forming the oblique columnar structures on the surface of the support. Any appropriate method can be adopted as a method of forming the oblique columnar structures. A preferred method is an oblique deposition process.

A method of imparting ultrahigh hydrophilicity to a surface of a base material the present invention is a method of imparting ultrahigh hydrophilicity to the surface of the base material, the method including forming, on the surface of the base material, an assembly layer of oblique columnar structures each protruding at an elevation angle from the surface of less than 90° by an oblique deposition process.

Any appropriate oblique deposition technology can be adopted as the oblique deposition process. For example, a method described in JP 08-27561 A can be adopted. A vacuum deposition apparatus is preferably used. It is also preferred that the oblique deposition process be performed by depositing a deposition material from the vapor onto the support or base material delivered by a roll. It is also preferred that the deposition material be obliquely deposited from the vapor onto the support or base material by providing a partial shield between a deposition source and the support or base material. The term “partial shield” as used herein refers to a state where, upon placement of a shield in a space between the deposition source and the support or base material, the shield is not placed so that the support or base material may be completely hidden when viewed from the deposition source. That is, the term refers to a state where the shield is placed so that at least part of the support or base material may appear when viewed from the deposition source.

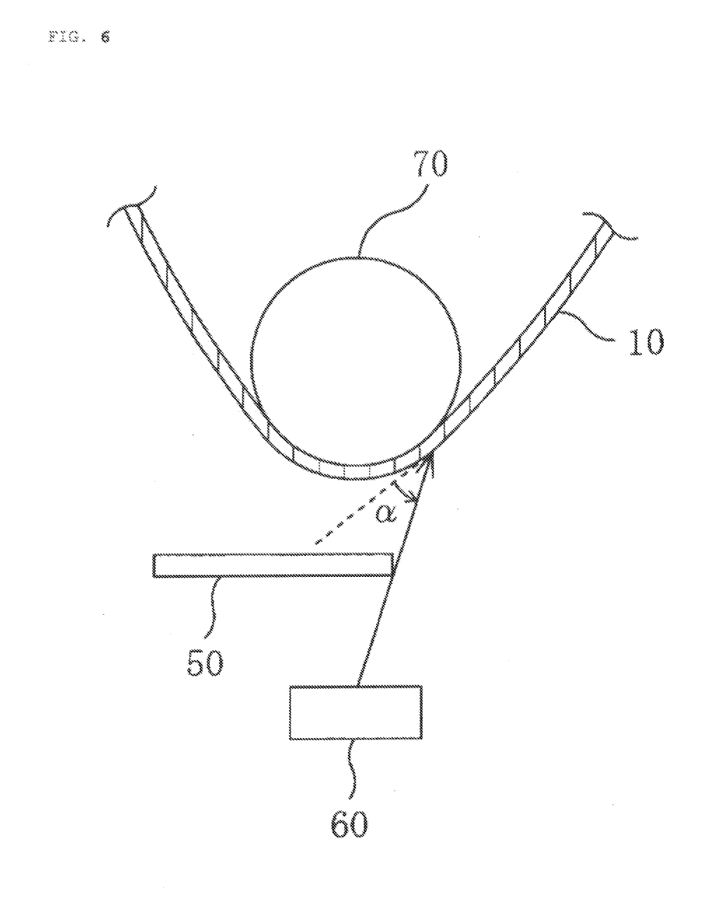

In a preferred embodiment, as illustrated in FIG. 6, when the deposition material as a deposition source 60 is vaporized or sublimated by heating so as to be caused to adhere to the surface of the support or base material 10 placed at a distant position in the chamber evacuated to a vacuum, a shield 50 is used, and the deposition material is deposited from the vapor while being tilted relative to the support or base material 10. When the deposition material is deposited from the vapor while being tilted relative to the support or base material 10, an oblique columnar structures 30 tilted relative to the surface of the support or base material 10 are formed. In this case, the support or base material 10 is delivered by a deposition roll 70. When such vacuum deposition apparatus as illustrated in FIG. 6 is used, a radius R of the deposition roll and a shortest distance L3 from the surface of the deposition roll to the deposition source each play a particularly important role in the design of the apparatus so that the surface of the support or base material can be provided with the assembly layer of the oblique columnar structures each protruding at an elevation angle of less than 90° from the surface of the support or base material and the oblique columnar structures may each be controlled to have an aspect ratio of 1 or more.

When such vacuum deposition apparatus as illustrated in FIG. 6 is used, any appropriate radius can be adopted as the radius R of the deposition roll as long as the surface of the support or base material can be provided with the assembly layer of the oblique columnar structures each protruding at an elevation angle of less than 90° from the surface of the support or base material and the oblique columnar structures can each be controlled to have an aspect ratio of 1 or more. The radius R of the deposition roll is preferably 0.1 to 5 m or more preferably 0.2 to 1 m in order that an effect of the present invention may be efficiently expressed.

When such vacuum deposition apparatus as illustrated in FIG. 6 is used, any appropriate distance can be adopted as the shortest distance L3 from the surface of the deposition roll to the deposition source as long as the surface of the support or base material can be provided with the assembly layer of the oblique columnar structures each protruding at an elevation angle of less than 90° from the surface of the support or base material and the oblique columnar structures can each be controlled to have an aspect ratio of 1 or more. The shortest distance L3 from the surface of the deposition roll to the deposition source is preferably 0.1 to 5 m or more preferably 0.3 to 3 m in order that the effect of the present invention may be efficiently expressed.

When such vacuum deposition apparatus as illustrated in FIG. 6 is used, any appropriate distance can be adopted as a shortest distance L1 from the center of the deposition roll to the deposition source as long as the surface of the support or base material can be provided with the assembly layer of the oblique columnar structures each protruding at an elevation angle of less than 90° from the surface of the support or base material and the oblique columnar structures can each be controlled to have an aspect ratio of 1 or more. It should be noted that the L1 is a length determined by L1=R+L3 Therefore, the shortest distance L1 from the center of the deposition roll to the deposition source is preferably 0.2 to 10 m or more preferably 0.5 to 4 m in order that the effect of the present invention may be efficiently expressed.

When such vacuum deposition apparatus as illustrated in FIG. 6 is used, any appropriate distance can be adopted as a shortest distance L2 from the shield to the deposition source as long as the surface of the support or base material can be provided with the assembly layer of the oblique columnar structures each protruding at an elevation angle of less than 90° from the surface of the support or base material and the oblique columnar structures can each be controlled to have an aspect ratio of 1 or more. Although the L2 is a length that can be set depending on the L3, in general, the L2 is preferably one half or more or more preferably two thirds or more of the L3 in order that the effect of the present invention may be efficiently expressed. When the L2 is smaller than the foregoing, a deposited film is apt to be formed isotropically, and hence it may be difficult to control the angle and the aspect ratio described above.

When such vacuum deposition apparatus as illustrated in FIG. 6 is used, any appropriate length can be adopted as a length L4 of the shield as long as the surface of the support or base material can be provided with the assembly layer of the oblique columnar structures each protruding at an elevation angle of less than 90° from the surface of the support or base material and the oblique columnar structures can each be controlled to have an aspect ratio of 1 or more. Although the L4 is a length that can be set depending on the R, a possible preferred setting is R<L4<2R because a deposition angle must be achieved. The L4 is preferably 0.1 to 10 m or more preferably 0.2 to 2 m. In addition, to be specific, the length L4 of the shield is adjusted so that the surface of the support or base material may be provided with the oblique columnar structures each protruding at an elevation angle α of less than 90° from the surface of the support or base material, preferably 10 to 85°, more preferably 20 to 80°, or still more preferably 30 to 70°. In the case of FIG. 5, the position of the right end of the shield 50 is adjusted in a horizontal direction.

The ultimate pressure in the above-mentioned vacuum deposition apparatus is preferably 1×10⁻³ torr or less, more preferably 5×10⁻⁴ torr or less, or still more preferably 1×10⁻⁴ torr or less. When the ultimate pressure in the above-mentioned vacuum deposition apparatus deviates from the above-mentioned range, it may be unable to form the oblique columnar structures with which the effect of the present invention can be sufficiently exerted.

The line rate at which the support or base material is delivered in the above-mentioned vacuum deposition apparatus has only to be set to any appropriate rate in consideration of, for example, the size of the apparatus so that the surface of the support or base material can be provided with the assembly layer of the oblique columnar structures each protruding at an elevation angle of less than 90° from the surface of the support or base material and the oblique columnar structures can each be controlled to have an aspect ratio of 1 or more.

Any appropriate method can be adopted for the vapor deposition of the deposition material in the above-mentioned vacuum deposition apparatus as long as the deposition material can be heated and vaporized by the method. The material is heated and vaporized by a method such as resistance heating, electron beams, high-frequency induction, or laser. The vapor deposition of the deposition material in the above-mentioned vacuum deposition apparatus is preferably performed by heating and vaporization with the electron beams.

The emission current of the above-mentioned electron beams has only to be set to any appropriate emission current in consideration of, for example, the size of the apparatus so that the surface of the support or base material can be provided with the assembly layer of the oblique columnar structures each protruding at an elevation angle of less than 90° from the surface of the support or base material and the oblique columnar structures can each be controlled to have an aspect ratio of 1 or more.

Any appropriate condition as well as the above-mentioned conditions can be adopted as a condition for the oblique deposition process. Conditions can be set by appropriately changing, for example, a deposition time, the degree of vacuum in the chamber, heating conditions (such as the output current of the electron beams or accelerating voltage), and a substrate temperature.

Any appropriate material can be adopted as the above-mentioned deposition material. For example, there may be used: metals such as aluminum, zinc, gold, silver, platinum, nickel, chromium, copper, and indium; inorganic materials such as sapphire, silicon carbide (SiC), and gallium nitride (GaN); and oxides such as silicon monoxide (SiO), silicon dioxide (SiO₂), aluminum oxide (Al₂O₃), cerium oxide (CeO₂), chromium oxide (Cr₂O₃), gallium oxide (Ga₂O₃), hafnium oxide (HfO₂), tantalum pentoxide (Ta₂O₅), yttrium oxide (Y₂O₃), tungsten oxide (WO₃), titanium monoxide (TiO), titanium dioxide (TiO₂), titanium pentoxide (Ti₃O₅), nickel oxide (NiO), magnesium oxide (MgO), ITO (In₂O₃+SnO₂), niobium pentoxide (Nb₂O₅), zinc oxide (ZnO), and zirconium oxide (ZrO₂). Further, there may be used: polyimides; fluorine-based materials such as aluminum fluoride, calcium fluoride, serium fluoride, lanthanum fluoride, lithium fluoride, magnesium fluoride, neodymium fluoride, and sodium fluoride; resins such as silicone; and the like. Those materials may be used alone or in a mixture, or there may be adopted a multilayer structure of two or more layers. In particular, there are suitably used oxides such as silicon dioxide (SiO₂) and titanium dioxide (TiO₂) which are hydrophilic materials.

The hydrophilic sheet of the present invention can be used in any appropriate application. A preferred example of the sheet is a hydrophilic sheet having an anti-fouling layer or an anti-fogging layer.

### Examples

Hereinafter, the present invention is described by way of examples. However, the present invention is not limited by those examples.

### [Water Contact Angle and Surface Free Energy]

A contact angle was measured with each of water and methylene iodide with respect to the surface of the assembly layer of oblique columnar structures, and surface free energy was calculated from the equation (1).

### [Evaluation for Anti-Fouling Performance]

Appropriate amounts of oil drops (NEOVAC MR-200 manufactured by Matsumura Oil Research Corp.) were mounted on the assembly layer of obliquely deposited structures of a hydrophilic sheet. After that, pure water was poured around the oil drops so as to surround the oil drops, and then the property by which the oil drops were removed with pure water was identified. The evaluation was performed on the basis of five sensory scales (5 was the best).

### [Evaluation for Anti-Fogging Performance]

A separator on the pressure-sensitive adhesive layer side of a hydrophilic sheet cut into a 10-cm square piece was peeled, and was then stuck to a window glass. After that, breath was blown on the assembly layer of oblique columnar structures, and then the anti-fogging performance of the window glass was identified. The evaluation was performed on the basis of five sensory scales (5 was the best).

### Example 1

### (Oblique Deposition Process)

A winding-up, electron-beam (EB) vacuum deposition apparatus illustrated in FIG. 6 was used in the formation of oblique columnar structures. The oblique columnar structures were produced by using a polyester film having a thickness of 50 μm (LUMIRROR S10 manufactured by Toray Industries, Inc.) as a base material and silicon dioxide (SiO₂) as an evaporation source under conditions of a line rate of 0.2 m/min, an ultimate pressure in the chamber of 4×10⁻⁵ torr, an EB output (emission current) of 500 mA, and a deposition incidence angle of 60°.

### (Production of Hydrophilic Sheet)

First, 2 parts of a polyisocyanate compound (manufactured by Nippon Polyurethane Industry Co., Ltd., trade name: Colonate L) and 0.6 part of an epoxy-based compound (manufactured by MITSUBISHI GAS CHEMICAL COMPANY, INC., trade name: TETRAD-C) were uniformly mixed into 100 parts of an acrylic polymer obtained from a monomer mixed liquid formed of 100 parts of butyl acrylate and 3 parts of acrylic acid. Thus, an acrylic pressure-sensitive adhesive solution was prepared. One surface of a polyester separator (manufactured by Mitsubishi Polyester Film, trade name: MRF50, thickness: 50 μm, width: 250 mm) was treated with a silicone-based releasing agent. The above-mentioned pressure-sensitive adhesive solution was applied onto the surface treated with the silicone-based releasing agent so as to have a thickness of 10 μm after its drying. Then, the solution was dried. The resultant was laminated on the other surface of the polyester film having a thickness of 50 μm where the oblique columnar structures were formed. Thus, a hydrophilic sheet was produced.

### (Evaluation)

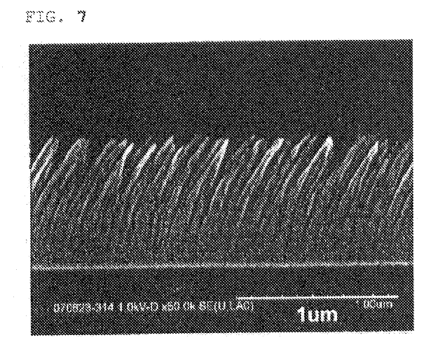

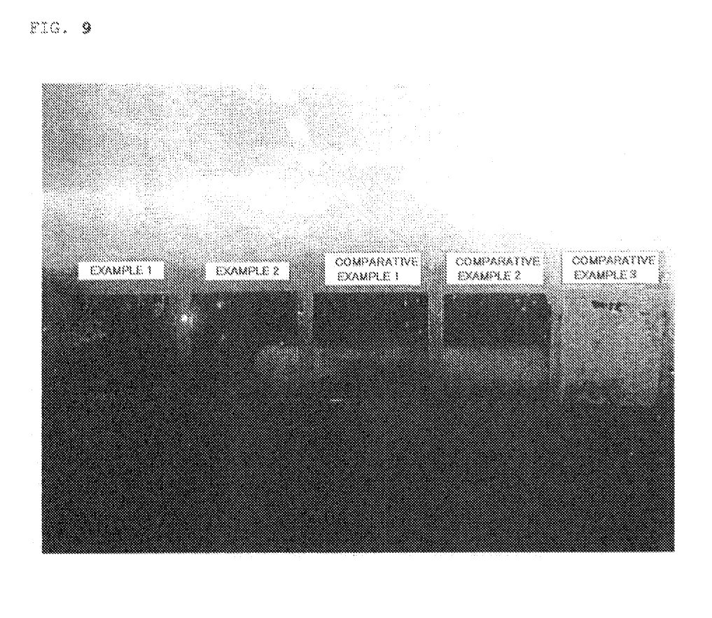

Table 1 shows the results of the evaluations. In addition, FIG. 7 illustrates an SEM photograph of a section of the resultant hydrophilic sheet. Further, FIG. 9 illustrates a photograph view of the evaluation for anti-fogging performance.

### Example 2

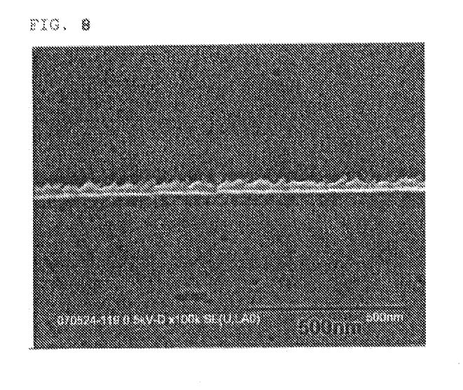

A hydrophilic sheet was produced by evaporating SiO₂ as the evaporation source to form the oblique columnar structures on the base material in the same manner as in Example 1 except that the line rate was set to 1.7 m/min. Table 1 shows the results of the evaluations. In addition, FIG. 8 illustrates an SEM photograph of a section of the resultant hydrophilic sheet. Further, FIG. 9 illustrates a photograph view of the evaluation for anti-fogging performance.

### Example 3

A hydrophilic sheet was produced by evaporating SiO₂ as the evaporation source to form the oblique columnar structures on the base material in the same manner as in Example 1 except that a 4-inch silicon wafer was used as the base material in the formation of the oblique columnar structures. Table 1 shows the results of the evaluations.

### Example 4

A hydrophilic sheet was produced by evaporating SiO₂ as the evaporation source to form the oblique columnar structures on the base material in the same manner as in Example 1 except that a polymethyl methacrylate (PMMA) resin having a thickness of 2 mm was used as the base material in the formation of the oblique columnar structures. Table 1 shows the results of the evaluations.

### Comparative Example 1

A hydrophilic sheet was produced by evaporating SiO₂ as the evaporation source to form the oblique columnar structures on the base material in the same manner as in Example 1 except that the line rate was set to 2.9 m/min. Table 1 shows the results of the evaluations. In addition, FIG. 9 illustrates a photograph view of the evaluation for anti-fogging performance.

### Comparative Example 2

A hydrophilic sheet was produced by evaporating SiO₂ as the evaporation source to form the oblique columnar structures on the base material in the same manner as in Example 1 except that the line rate was set to 4.3 m/min. Table 1 shows the results of the evaluations. In addition, FIG. 9 illustrates a photograph view of the evaluation for anti-fogging performance.

### Comparative Example 3

A sheet formed of a pressure-sensitive adhesive layer on one surface was produced without the formation of any oblique columnar structure. Table 1 shows the results of the evaluations. In addition, FIG. 9 illustrates a photograph view of the evaluation for anti-fogging performance.

TABLE 1

| | Example | Example | Example | Example | Comparative | Comparative | Comparative |
|---|---|---|---|---|---|---|---|
| | 1 | 2 | 3 | 4 | Example 1 | Example 2 | Example 3 |
| Line rate (m/min) | 0.2 | 1.7 | 0.2 | 0.2 | 2.9 | 4.3 | — |
| Water contact angle | 5.3 | 5.4 | 4.4 | 7.2 | 11.5 | 14.4 | 103.6 |
| (degrees) | | | | | | | |
| Methylene iodide | 4.6 | 6.2 | 16.6 | 18.9 | 10.7 | 14.8 | 81.9 |
| contact angle | | | | | | | |
| (degrees) | | | | | | | |
| Surface free energy | 76.0 | 75.9 | 75.4 | 74.9 | 74.8 | 73.9 | 17.0 |
| (mJ/m²) | | | | | | | |
| Anti-fouling | 5 | 4 | 5 | 5 | 2 | 2 | 1 |
| performance | | | | | | | |
| Anti-fogging | 5 | 4 | 5 | 5 | 3 | 2 | 1 |
| performance | | | | | | | |

### INDUSTRIAL APPLICABILITY

The hydrophilic sheet of the present invention or a hydrophilic member obtained by the method of the present invention is applicable to, for example, an anti-fouling sheet which has high wettability by water and from which an adherent fouling substance or adherent foreign matter can be easily removed by washing with water or an anti-fogging sheet that can be prevented from fogging due to water-drop adhesion.

1. A hydrophilic sheet comprising, on a surface of a support, an assembly layer of oblique columnar structures each protruding at an elevation angle from the surface of less than 90°, wherein a surface of the assembly layer has a water contact angle of 10° or less.

2. A hydrophilic sheet according to claim 1, wherein:
the hydrophilic sheet comprises, on one surface of the support, the assembly layer of the oblique columnar structures each protruding at an elevation angle from the surface of less than 90°;
the surface of the assembly layer has a water contact angle of 10° or less; and
a pressure-sensitive adhesive layer is formed on another surface of the support.

3. A hydrophilic sheet according to claim 1, wherein the assembly layer comprises an anti-fouling layer.

4. A hydrophilic sheet according to claim 1, wherein the assembly layer comprises an anti-fogging layer.

5. A method of imparting ultrahigh hydrophilicity to a surface of a base material, the method comprising forming, on the surface of the base material, an assembly layer of oblique columnar structures each protruding at an elevation angle from the surface of less than 90° by an oblique deposition process.

6. A method of imparting ultrahigh hydrophilicity to a surface of a base material according to claim 5, wherein a vacuum deposition apparatus is used in the oblique deposition process.

7. A method of imparting ultrahigh hydrophilicity to a surface of a base material according to claim 6, wherein an ultimate pressure in the vacuum deposition apparatus is 1×10⁻³ ton or less.

8. A method of imparting ultrahigh hydrophilicity to a surface of a base material according to claim 6, wherein vapor deposition of a deposition material in the vacuum deposition apparatus is performed by heating and vaporization with electron beams.

9. A method of imparting ultrahigh hydrophilicity to a surface of a base material according to claim 5, wherein the oblique deposition process is performed by depositing a deposition material from vapor onto the base material delivered by a roll.

10. A method of imparting ultrahigh hydrophilicity to a surface of a base material according to claim 5, wherein the oblique deposition process involves obliquely depositing a deposition material from vapor onto the base material by providing a partial shield between a deposition source and the base material.

11. A method of imparting ultrahigh hydrophilicity to a surface of a base material according to claim 5, wherein the assembly layer has a thickness of 10 nm or more.

12. A method of imparting ultrahigh hydrophilicity to a surface of a base material according to claim 5, wherein a number of the oblique columnar structures per unit area of the surface of the base material is 1×10⁸ structures/cm² or more.

13. A method of imparting ultrahigh hydrophilicity to a surface of a base material according to claim 5, wherein a surface of the assembly layer has a water contact angle of 10° or less.
